(19) United States
(12) Patent Application Publication
(10) Pub. No.: US 2026/0171377 A1
(43) Pub. Date: Jun. 18, 2026

(54) PLASMA MONITORING APPARATUS

(71) Applicant: Samsung Electronics Co., Ltd., Suwon-si (KR)

(72) Inventors: Jehoi Mun, Suwon-si (KR); Sungho Jang, Suwon-si (KR); Pyungkee Kim, Suwon-si (KR); Sang Ki Nam, Suwon-si (KR)

(21) Appl. No.: 19/310,177

(22) Filed: Aug. 26, 2025

(30) Foreign Application Priority Data
Dec. 16, 2024 (KR) 10-2024-0187683

(51) Int. Cl. H01J 37/32

(52) U.S. Cl. CPC H01J 37/32972; H01J 37/3244; H01J 2237/334

(57) ABSTRACT

The present disclosure relates to a plasma monitoring apparatus including a plasma chamber including a processing zone for processing a substrate by using a plasma; an optical detector disposed spaced apart from the plasma chamber and detecting an optical signal generated from the plasma; and a connection section connecting the plasma chamber and the optical detector, wherein the optical detector includes an optical detection chamber, a gas exhaust section positioned below the optical detection chamber and removing a reaction gas inflowed from the plasma chamber, a window placed on one side of the optical detection chamber and through which the optical signal is transmitted, and a first determining section determines the processing by using the optical signal passing through the window.

### CROSS-REFERENCE TO RELATED APPLICATION

This application claims priority to and the benefit of Korean Patent Application No. 10-2024-0187683 filed with the Korean Intellectual Property Office on Dec. 16, 2024, the entire contents of which are incorporated herein by reference.

### BACKGROUND

Semiconductor processes require a precise process control in a nanometer (nm) unit, and plasma-based processes are used for this purpose. The plasma is created by ionizing a gas with high temperature or electrical energy, and is used in semiconductor processes such as an etching, a deposition, or a cleaning. The characteristics of these plasma processes are largely determined by physical and chemical states of ions, electrons, neutral atoms, and molecules present in the plasma.

Accordingly, a technology to diagnose and analyze plasma status in real time plays a very important role in maintaining a process quality and stability. Non-contact methods such as an optical emission spectroscopy (OES) are used as techniques for plasma diagnosis. For example, the optical emission spectroscopy analyzes an optical signal emitted from the plasma to detect irregularities in the semiconductor process at an early stage through analysis of the presence of chemical species in the plasma, a concentration, a temperature, an electron density, etc., and to appropriately control the process conditions to reduce a defect rate.

### SUMMARY

When optical signals are analyzed through a window placed on the plasma chamber side wall, the window may exhibit a problem in that during the plasma process, a reactive gas is deposited on the window or reacts with the window, causing a portion of the window to be etched. When the optical signal is detected by the spectrometer through the window, the optical signal is distorted by the window being deposited or etched with some material by the reaction gas.

Additionally, there may be difficulty in detecting lower wavelengths that visible light, such as extreme ultraviolet rays (EUV), which do not pass through the window.

Some aspects of the present disclosure provide plasma monitoring apparatuses that mitigate the problem of the gas material being deposited on the window or partially etching the window, and mitigate the distortion of the optical signal generated from the plasma, thereby maintaining the quality and stability of the semiconductor process for the substrate.

Some aspects of the present disclosure provide plasma monitoring apparatuses that can detect not only the wavelength of the visible ray region among the optical signals generated from the plasma, but also the wavelength of ultraviolet rays, which are lower than the visible ray, thereby maintaining the quality and stability of the semiconductor process for the substrate.

A plasma monitoring apparatus according to some implementations of the present disclosure may include a plasma chamber including a processing zone for processing a substrate by using a plasma; an optical detector disposed spaced apart from the plasma chamber and detecting an optical signal generated from the plasma; and a connection section connecting the plasma chamber and the optical detector, wherein the optical detector includes an optical detection chamber, a gas exhaust section positioned below the optical detection chamber and removing a reaction gas inflowed from the plasma chamber, a window placed on one side of the optical detection chamber and through which the optical signal is transmitted, and a first determining section determines the processing by using the optical signal passing through the window.

According to some implementations of the present disclosure, a plasma monitoring apparatus may include a plasma chamber including a processing zone for processing a substrate by using a plasma; an optical detector disposed spaced apart from the plasma chamber and detecting an optical signal generated from the plasma; and a connection section connecting the plasma chamber and the optical detector, wherein the optical detector includes an optical detection chamber, a gas exhaust section positioned below the optical detection chamber and removing a reaction gas inflowed from the plasma chamber, a diffraction lattice arranged on the same horizontal line as the optical signal inflowing through the connection section, and separating the optical signal according to a wavelength, and a second determining section that determines the processing by using a second optical signal separated from the diffraction lattice.

According to some implementations of the present disclosure, a plasma monitoring apparatus may include a plasma chamber including a processing zone for processing a substrate by using a plasma; an optical detector disposed spaced apart from the plasma chamber and detecting an optical signal generated from the plasma; and a connection section connecting the plasma chamber and the optical detector, wherein the optical detector includes an optical detection chamber, a gas exhaust section positioned below the optical detection chamber and removing a reaction gas inflowed from the plasma chamber, a diffraction lattice that separates the optical signal into a first optical signal and a second optical signal of a shorter wavelength than the first optical signal, a window through which the first optical signal passes, a first determining section that determines the processing by using the first optical signal passing through the window, and a second determining section that determines the processing by using the second optical signal.

According to some implementations the present disclosure, the plasma monitoring apparatus includes the gas exhaust section within the optical detector to the remove reaction gas, thereby preventing the gas material from being deposited on the window or partially etching the window, and preventing a distortion of the optical signal resulting from the plasma, thereby maintaining the reliability and stability of the semiconductor process for the substrate.

According to some implementations of the present disclosure, the plasma monitoring apparatus includes the diffraction lattice in the optical detector and the determining unit that may determine the wavelength value according to each wavelength, thereby enabling the detection of not only the wavelength of the visible ray region among the optical signals generated from the plasma, but also the wavelength of extreme ultraviolet rays, which are lower wavelengths than the visible ray, thereby maintaining the reliability and stability of the semiconductor process for the substrate.

### BRIEF DESCRIPTION OF THE DRAWINGS

FIG. 1 is a diagram illustrating an example of a plasma monitoring apparatus.

FIG. 2 is a diagram illustrating an example of a plasma monitoring apparatus

FIG. 3 to FIG. 6 are enlarged views of region A of FIG. 2.

FIG. 7 is a diagram illustrating an example of a plasma monitoring apparatus

FIG. 8 and FIG. 9 are enlarged views of region B of FIG. 7.

FIG. 10 is a diagram illustrating an example of a plasma monitoring apparatus

FIG. 11 and FIG. 12 are enlarged views of region C of FIG. 10.

FIG. 13 is a diagram illustrating an example of a plasma monitoring apparatus.

FIG. 14 to FIG. 20 are diagrams illustrating examples of plasma monitoring apparatuses.

FIG. 21 is an enlarged view of region D of FIG. 20.

### DETAILED DESCRIPTION

As those skilled in the art will realize, the disclosed examples may be modified in various different ways, combined, and the like, without departing from the spirit or scope of the present disclosure.

Descriptions of parts not related to the present disclosure are omitted, and like reference numerals designate like elements throughout the specification.

Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., may be exaggerated for clarity.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

In addition, unless explicitly described to the contrary, the word “comprise”, and variations such as “comprises” or “comprising”, will be understood to imply the inclusion of stated elements but not the exclusion of any other elements.

Further, in the specification, the phrase “in a plan view” means when an object portion is viewed from above, and the phrase “in a cross-sectional view” means when a cross-section taken by vertically cutting an object portion is viewed from the side.

Additionally, terms such as “ . . . part”, “ . . . device”, and “ . . . module” described in the specification, where the terms perform or are configured to perform at least one function or operation, may be implemented by a hardware or a software, or by a combination of a hardware and a software. Additionally, a plurality of “ . . . module”, a plurality of “ . . . device”, or a plurality of “ . . . module” may be integrated into at least one module and implemented as at least one processor, except for “ . . . part”, “ . . . device”, and “ . . . module” that need to be implemented by a specific hardware as described explicitly or clearly indicated by context or knowledge in the art.

In this specification, “transmitting” or “providing” may include not only directly transmitting or providing, but also indirectly transmitting or providing via another device or using a bypass path.

In the description, expressions described in the singular in this specification may be interpreted as the singular or plural unless an explicit expression such as “one” or “single” is used.

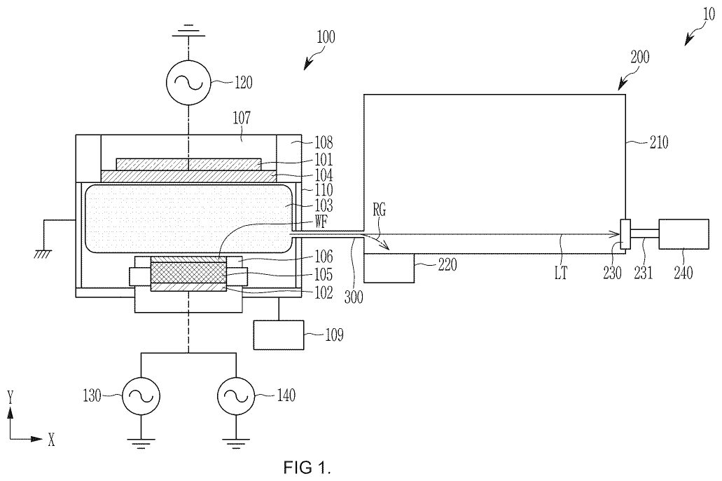

FIG. 1 illustrates an example of a plasma monitoring apparatus 10.

Referring to FIG. 1, the plasma monitoring apparatus 10 may analyze a state of a substrate WF, and/or other process statuses, parameters, characteristics, and/or the like, by receiving and detecting an optical signal emitted from a plasma in a substrate processing device 100 using an optical detector 200. For example, the plasma monitoring apparatus 10 may monitor the processing status, uniformity, or abnormality of the substrate in real time based on the plasma optical signal, thereby managing the quality of a semiconductor process.

The plasma monitoring apparatus 10 includes a plasma chamber 110 including a processing zone for processing the substrate WF using a plasma, an optical detector 200 disposed at the side of the plasma chamber 110 (e.g., spaced apart from the plasma chamber 110) and detecting the optical signal generated from the plasma, and a connection section 300 connecting the plasma chamber 110 and the optical detector 200. In this way, the plasma monitoring apparatus 10 determines the processing, status, characteristics, and/or the like of the semiconductor process by detecting the optical signal generated from the plasma in the plasma chamber 110 through the connection section 300 and in the optical detector 200.

The substrate processing device 100 includes the plasma chamber 110 for processing the substrate WF. The substrate processing device 100 is a device that performs a plasma process on the substrate, and may form the plasma by applying a gas and an electric field to the plasma chamber and process the substrate using the plasma. For example, the substrate processing device 100 may perform an etching (Etch) process of the substrate WF by using an excited plasma. For example, the substrate processing device 100 may be a device such as an inductively coupled plasma (ICP), a capacitive coupled plasma (CCP), or a high density plasma (HDP). In the present disclosure, the substrate processing device 100, which is the plasma device, is illustrated as the capacitive coupling plasma (CCP) device that generates the electric field by applying an RF voltage between two electrodes and the electric field ionizes the gas to generate the plasma, but this is an example, and the present disclosure may be applied to any device that includes a plasma chamber and generates a plasma.

The substrate WF may be a wafer for manufacturing a semiconductor device. For example, the substrate WF may include an element-semiconductor material such as silicon (Si) or germanium (Ge), a compound-semiconductor material such as silicon germanium (SiGe) or gallium arsenic (GaAs), or a dielectric material such as quartz or sapphire.

The plasma chamber 110 may provide a processing zone 103 in which a substrate treatment process is performed by the electric field applied from the upper electrode 101 and the lower electrode 102. For example, the plasma chamber 110 may have a processing zone 103 that electrically reacts the process gas inflowed therein to perform the semiconductor process, and the processing zone 103 may be provided in a close and sealed shape. The plasma chamber 110 may be provided in a metallic material. As an example, the plasma chamber 110 may include a material such as aluminum.

The upper electrode 101 may be placed within the plasma chamber 110. For example, the upper electrode 101 may be grounded or coupled to an upper RF generator 120. The lower electrode 102 may be placed within the plasma chamber 110 and face the upper electrode 101. The lower electrode 102 may be grounded or coupled to the lower bias generator 130. The substrate processing device 100 may be a capacitive coupling plasma facility that may independently include the upper electrode 101 and the lower electrode 102 within the plasma chamber 110.

The upper electrode 101 and the lower electrode 102 may be arranged facing each other inside the plasma chamber 110. For example, the upper electrode 101 and the lower electrode 102 may be arranged in a vertical direction facing each other inside the plasma chamber 110.

The processing zone 103 may be a region where the process gas inflowed into the plasma chamber 110 is excited into the plasma by the electric field formed by the upper electrode 101 and the lower electrode 102. For example, the process gas may be excited into the plasma by a capacitive coupling plasma source.

The plasma may be formed when a high-frequency (RF) power is supplied between the electrodes to form the electric field, and the gas between the electrodes is ionized by the electric field. The plasma may mean a state in which separated ions and electrons are each separated and mixed.

The plasma may be composed of high-energy ions and electrons and react with the surface of the substrate WF faster than general chemical reactions. For example, the plasma may have a uniform potential distribution, so that the surface of the substrate WF may be evenly processed inside the plasma chamber 110. At this time, the process may be performed by controlling the density and energy of the plasma.

In some implementations, a showerhead 104 may be placed within the plasma chamber 110. The showerhead 104 may be positioned on the upper electrode 101 to supply a process gas into the plasma chamber 110. The showerhead 104 supplies the process gas in the WF direction toward the substrate positioned below the plasma chamber 110, and the process gas may be excited into a plasma.

In some implementations, the process may be performed while the substrate WF is fixed by an electrostatic chuck 105. The electrostatic chuck 105 may be a member that is positioned inside the plasma chamber 110 to fix the substrate WF so that it does not move during a process such as an etching. For example, the electrostatic chuck 105 may fix the substrate WF with a static electricity force, thereby preventing the movement of the substrate WF during the process using the plasma generated from the process gas.

In some implementations, the substrate WF may be surrounded by a focus ring 106. For example, the focus ring 106 may be a device positioned at the edge of the substrate to assist in increasing the concentration of the plasma on the substrate WF during the process or in maintaining the uniformity of the process.

In some implementations, the upper electrode 101 may be surrounded by a symmetrical RF ground electrode 108. The symmetric RF ground electrode 108 may be a member that stabilizes the flow of electrons and ions and forms the uniform plasma.

In some implementations, an insulator 107 may be included between the upper electrode 101 and the symmetrical RF ground electrode 108. The insulator 107 may be a dielectric material positioned between the upper electrode 101 and the symmetrical RF ground electrode 108 to isolate the upper electrode 101 and the symmetrical RF ground electrode 108.

In some implementations, the plasma chamber 110 may include an exhaust member 109. The exhaust member 109 may allow the process gas to be pumped from the plasma chamber 110 by a gas pump. The exhaust member 109 may be placed in the lower region of the plasma chamber 110. For example, the exhaust member 109 may be placed on, or connected to, the lower wall of the plasma chamber 110. The exhaust member 109 may discharge reaction byproducts generated during the process and gases remaining in the internal space of the plasma chamber 110 to the outside.

In some implementations, when the gas is discharged to the outside through the exhaust member 109, the inside of the plasma chamber 110 may be depressurized to a predetermined pressure. In some implementations, the exhaust member 109 may include at least one pump, which may include, as an example, a turbo molecular pump. In some implementations, the exhaust member 109 may include a valve. The valve may be controlled with a shutoff, thereby regulating the flow rate of the gas.

The substrate processing device 100 may include an RF generator 120 and bias generators 130 and 140 to generate the plasma. The RF generator 120 may be used to increase the plasma density to maintain the plasma state, and the ionize the gas. The bias generators 130 and 140 may control the depth of the process and the surface quality of the substrate WF by controlling the speed and energy at which ions in the plasma move to the wafer surface. The RF generator 120 and the bias generators 130 and 140 may form the plasma in a triode reactor and precisely process the substrate WF by utilizing different frequency bandwidths. Although the present disclosure discloses the triode reactor, this is an example, and various reactors that generate a plasma are within the scope of this disclosure, such as a diode reactor.

The RF generator 120 may supply an electric power used to generate and maintain the plasma by using a high frequency (HF) band. The high frequency may be, as an example, 10 to 100 MHz. For example, the RF generator 120 may ionize the process gas by forming a high-frequency electric field within the plasma chamber 110. The high-frequency electric field may induce collisions between electrons and process gas molecules to be converted into a plasma state, thereby increasing the plasma density. For example, the RF generator 120 rapidly accelerates the electrons to high energy by using a high-frequency electric power HF source, and when the electrons collide the gas molecules, the ionization reaction may be performed to form the plasma.

The bias generators 130 and 140 are electrically connected to the lower electrode 102 and provide an electric power for a bias. When the bias generators 130 and 140 apply a bias electric power to the lower electrode 102, which creates a potential difference between the electrode and the plasma, positive ions are accelerated and collide the wafer surface. The bias electric power may control the collision energy of ions, for example, the state of the plasma sheath, the concentration state of the plasma on the substrate, the incidence state of ions on the substrate, and the depth and speed of the etching in processes such as an etching. As an example, the bias generators 130 and 140 are shown separately only to indicate a bias electric power, and may generate a low frequency electric power from a single bias generator, e.g., only a single bias generator may be included.

The bias generators 130 and 140 may generate the electric power at a lower frequency than the HF source to be supplied to the lower electrode 102. For example, the bias generators 130 and 140 may include a first bias generator 130 that generates a middle frequency (MF) and a second bias generator 140 that generates a low frequency (LF). As the bias generators 130 and 140 supply the electric power with different frequency bandwidths to the lower electrode 102, the energy of ions may be precisely controlled.

The first bias generator 130 may supply a lower MF source than the HF source. By supplying the MF source by the middle frequency to the lower electrode 102, the ion energy may be maintained uniformly and the accuracy of the surface treatment may be improved.

The second bias generator 140 may supply the lower LF source than the MF source. The LF source by the low frequency is supplied to the lower electrode 102, thereby lowering the average energy of ions and reducing a surface damage.

The optical detector 200 may detect an optical signal generated from the plasma within the plasma chamber 110. For example, the optical detector 200 may receive a portion of the optical signal from the plasma and detect the optical signal to identify the semiconductor process.

In some implementations, the optical detector 200 may be positioned spaced apart from the side of the plasma chamber 110. The optical detector 200 may be placed spaced apart from the plasma chamber 110 and be connected to the plasma chamber 110 by the connection section 300 that connects the plasma chamber 110 and the optical detector 200. For example, the optical signal generated from the plasma in the plasma chamber 110 inflows into the optical detector 200 through the connection section 300, and the processing of the substrate may be determined by detecting the optical signal in the optical detector 200 for the inflowed optical signal.

In some implementations, the optical detector 200 may include an optical detection chamber 210, a gas exhaust section 220, a window 230, and a first determining section 240. For example, the optical detector 200 may separate the reaction gas RG from the optical signal LT (from among the optical signal LT and the reaction gas RG inflowed from the plasma chamber 110), and detect the optical signal LT to determine the processing of the substrate.

The optical detection chamber 210 may provide a space in which a process of detecting the optical signal LT inflowed into the optical detector 200 is performed. For example, the optical detection chamber 210 may provide the space in which a process of removing the reaction gas RG and detecting the optical signal LT is performed.

In some implementations, the optical detection chamber 210 may be provided as a metallic material. As an example, the optical detection chamber 210 may include a material such as aluminum. For example, the optical detection chamber 210 may be provided with the same or similar material as the plasma chamber 110.

The gas exhaust section (or gas exhaust module) 220 may remove the reaction gas RG that flows into the optical detector 200. For example, not only the optical signal LT but also the reaction gas RG may be inflowed together from the plasma chamber 110 to the optical detector 200. The reaction gas RG may act as a noise when detecting the optical signal LT in the first determining section 240. For example, the reaction gas RG may deteriorate the sensitivity of the optical signal LT, and react with the window 230 so that the optical signal LT may pass through the window 230 with a distortion. In this way, the gas exhaust section 220 may prevent or reduce the distortion caused by the reaction gas RG when the optical signal LT passes through the window 230.

In some implementations, the gas exhaust section 220 may include at least one pump. The gas exhaust section 220 may include, as an example, a turbo molecular pump. The gas exhaust section 220 may include an intake configured to receive the reaction gas RG from an interior of the optical detection chamber 210.

In some implementations, the gas exhaust section 220 may be arranged adjacent to the connection section 300. For example, the gas exhaust section 220 may be arranged below the optical detection chamber 210 and may be arranged at a position lower than the end of the connection section 300. Since the gas exhaust section 220 is positioned adjacent to the connection section 300 and at the lower position than the connection section 300, only the reaction gas RG that flows into the connection section 300 may be targeted and efficiently removed without affecting the optical signal LT, which transmits in a line.

The window 230 may be placed on one side of the optical detection chamber 210. For example, the window 230 may be provided to penetrate the inner side and the exterior side of the optical detection chamber 210 and provide the optical signal to the outside of the optical detection chamber 210. For example, the window 230 may provide a path for the optical signal that inflows into the optical detection chamber 210 via the connection section 300 to travel to the outside.

In some implementations, the window 230 may further include a shield member. The shield member may shield the inside and outside of the optical detection chamber 210. As an example, the shield member may be a material such as glass, quartz, or fused silica having a ring shape. In some implementations, the shield member may correspond to the side wall thickness of the optical detection chamber 210, be smaller than the side wall thickness, and be positioned over the entire or part of the window 230.

The first determining section 240 (sometimes referred to as an optical analyzer or an optical sensor module, and which may include at least one sensor for detecting the optical signal) may detect a light radiating from the inside of the optical detection chamber 210 from the plasma chamber 110. For example, the first determining section 240 may detect and analyze the optical signal LT that has passed through the window 230. The first determining section 240 can be configured to diagnose the plasma based on characteristics such as the emission, absorption, or scattering of the optical signal LT, and through the plasma diagnosis, it may be determined whether the processing of the substrate is being performed appropriately.

In some implementations, the first determining section 240 may include at least one of an optical emission spectroscopy (OES) module, a laser absorption spectroscopy (LAS) module, a tunable diode laser absorption spectroscopy (TDLAS) module, a laser-induced breakdown spectroscopy module, a Fourier-transform infrared spectroscopy module, a cavity ring-down spectroscopy (CRDS) module, a tunable laser spectroscopy module, and an ellipsometry module. For example, the first determining section 240 may be an optical emission spectroscopy (OES) module. The first determining section 240 may include one or more optical sensors concomitant with the module type. For example, the first determining section 240 may include an OES sensor, an LAS sensor, a TDLAS sensor, etc.

In some implementations, the optical detector 200 may further include a light collecting section 231 positioned between the window 230 and the first determining section 240. The light collecting section 231 may stably and efficiently transmit the optical signal LT transmitted through the window 230 to the first determining section 240. For example, the light collecting section 231 may be an optical fiber, and the optical fiber may be used to focus the optical signal LT more efficiently in the high temperature environment of the chamber.

The connection section 300 may connect the plasma chamber 110 and the optical detector 200. The connection section 300 may connect a hole formed in a part of the side wall of the plasma chamber 110 and a hole formed in a part of the side wall of the optical detection chamber 210. The connection section 300 may connect the holes of the aforementioned chamber so that the optical signal LT may flow from the plasma inside the plasma chamber 110 to the optical detector 200. For example, the holes formed in the plasma chamber 110 and the optical detection chamber 210 may be arranged facing each other.

In some implementations, the connection section 300 may have a straight line shape. For example, the connection section 300 may be a member through which the optical signal LT generated from plasma flows, and since the optical signal LT has a linear transmission path, the optical signal LT may easily flow from the plasma chamber 110 to the optical detection chamber 210.

In some implementations, the connection section 300 may be in a pipe or tube shape. For example, the connection section 300 may be a tube that connects the holes formed in a portion of the side wall of the plasma chamber 110 and the optical detection chamber 210. For example, the cross-section of the tube may be a circle, a square, a pentagon, or a polygon.

As above-described, according to some implementations of the present disclosure, when the optical signal LT radiated from the plasma chamber 110 in the substrate processing device 100 is detected by the optical detector 200, the plasma monitoring apparatus 10 may minimize or otherwise reduce the reaction of the reaction gas RG with the window 230 and prevent a distorted optical signal from being transmitted to the first determining section 240.

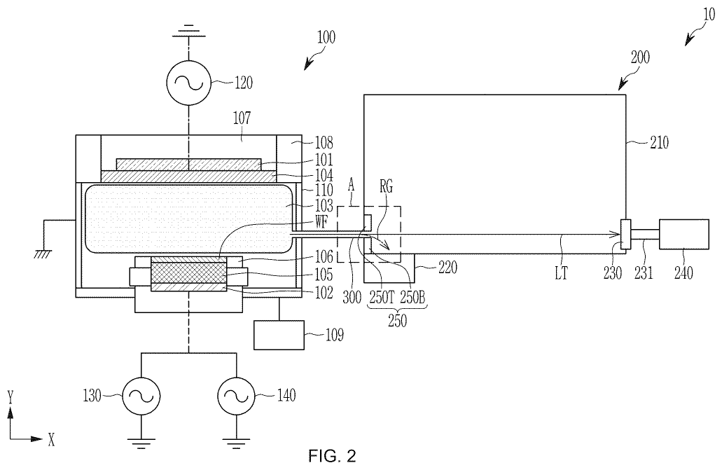

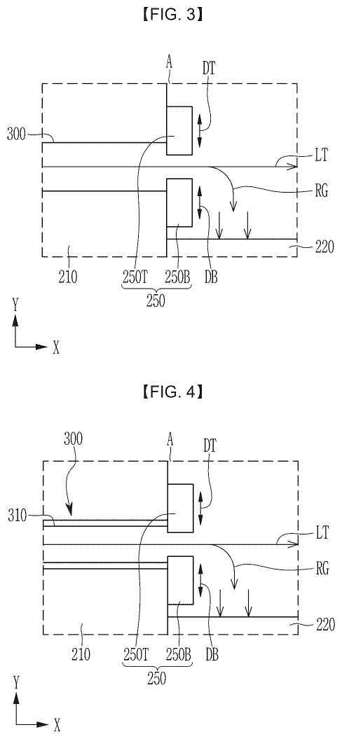

FIG. 2 is a diagram illustrating an example of a plasma monitoring apparatus 10, and FIG. 3 to FIG. 6 are enlarged views of a region A of FIG. 2. The apparatus 10 of FIG. 2 may be substantially similar to that of FIG. 1 except where noted otherwise, and differences therebetween are mainly described.

Referring to FIGS. 2 and 3, in some implementations, the optical detector 200 may include a slit section 250 for controlling the amount of light of the optical signal LT. For example, the slit section 250 may appropriately control the amount of light of the optical signal LT that inflows from the plasma chamber 110 through the connection section 300, and may also control the amount of the inflow of the reaction gas RG. For example, the slit section 250 may increase the amount of light of the optical signal LT that inflows through the connection section 300 and reduce the amount of the inflow of the reaction gas RG, thereby improving the reliability of the optical signal LT that reaches the window 230. A vacuum may be maintained within the plasma chamber 110 by the slit section 250. For example, the slit section 250 may be designed to be shutoff-capable to control the vacuum pressure of the plasma chamber 110, to maintain the vacuum as well as the inflow amount of the reaction gas RG and optical signal LT.

In some implementations, the slit section 250 may include an upper shutter 250T and a lower shutter 250B. The slit section 250 may include the upper shutter 250T and the lower shutter 250B positioned below the upper shutter 250T. The upper shutter 250T and the lower shutter 250B may be positioned opposite each other along a a Y-axis, which is a vertical direction. The upper shutter 250T and the lower shutter 250B move in the Y-axis direction and may control the amount of light of the optical signal LT.

In some implementations, the upper shutter 250T may move in the first direction (or within a first range) DT and the lower shutter 250T may move along the second direction (or within a second range) DB. The first direction DT and the second direction DB may be along the axis Y. The upper shutter 250T and the lower shutter 250T may move along the first direction DT and the second direction DB, respectively (e.g., within respective ranges), and control the amount of the optical signal LT inflowing into the optical detection chamber 210 and the inflowing amount of the reaction gas RG.

In some implementations, the upper shutter 250T and the lower shutter 250B may move at the same interval along the first direction DT and the second direction DB to control the amount of light of the optical signal LT. For example, the upper shutter 250T and the lower shutter 250B may move at the same interval, or have the same movement direction, along the Y-axis direction.

In some implementations, the upper shutter 250T and the lower shutter 250B may move at different intervals or directions along the first direction DT and the second direction DB to control the amount of light of the optical signal LT. For example, the upper shutter 250T and the lower shutter 250B may move at different intervals or directions along the Y-axis direction.

For example, the upper shutter 250T may move in the upper direction, and the lower shutter 250B may move in the down direction, to widen the interval between the slit sections 250 to control the amount of light and the inflow amount of the reaction gas. The upper shutter 250T and the lower shutter 250B may move in the same direction (e.g., both upward or both downward), thereby controlling not only the amount of the inflow of the optical signal LT and the reaction gas RG, but also the direction thereof.

FIG. 3 illustrates that the upper shutter 250T and the lower shutter 250B are separated, but this is an example, and other shapes/configurations are within the scope of this disclosure. For example, the upper shutter 250T and the lower shutter 250B may have an integrated or concentric ring shape, and controlling the inner diameter of the ring may also include controlling the amount of light.

Referring to FIG. 4, in some implementations, the connection section 300 may include a guiding section 310 that assists the inflow of the optical signal LT therein. For example, the guiding section 310 may play a role in facilitating the inflow of the optical signal LT into the optical detection chamber 210 when the optical signal LT is transmitted from the plasma chamber 110.

In some implementations, the guiding section 310 may have a cross-section shape that is a polygon, a circle, an ellipse, or a combination thereof. For example, the guiding section 310 may be positioned inside the connection section 300 and may have the same cross-section shape as the connection section 300. This is an example, and the cross-section shape of the connection section 300 and the guiding section 310 may be manufactured to have various suitable shapes under the condition of minimizing/reducing the interference for the optimal structural stability and linearity of the optical signal LT, depending on the intended use and requirements.

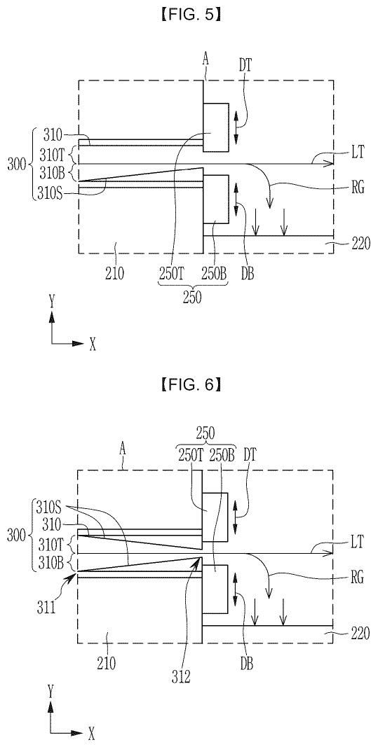

Referring to FIG. 5, in some implementations, the guiding section 310 may include an upper region 310T and a lower region 310B on the cross-section. For example, the guiding section 310 may be divided into the upper region 310T and the lower region 310B, with the X-axis passing through the center of the guiding section 310 as a reference.

In some implementations, the guiding section 310 may include an inclined portion 310S in at least one of the upper region 310T and the lower region 310B in the cross-section. For example, the inclined portion 310S may mean a region in which the upper region 310T or the lower region 310B has a predetermined slope in the cross-section.

The inclined portion 310S may assist in controlling the amount of light of the optical signal LT and the inflow amount of the reaction gas RG by allowing the upper region 310T or the lower region 310B to have the predetermined slope. For example, the guiding section 310 may include the inclined portion 310S to assist in focusing the optical signal LT to be supplied to the optical detection chamber 210. The guiding section 310S includes the inclined portion 310S, so that a portion of the reaction gas RG is blocked by the inclined portion 310S, thereby reducing the amount of the reaction gas RG that flows into the optical detection chamber 210.

In FIG. 5, the inclined portion 310S is depicted as being included only in the lower region 310B and as being included throughout the lower region 310B, but this is an example and other arrangements are within the scope of this disclosure. For example, the inclined portion 310S may included only in the upper region 310T, also included in the upper region 310B, or included in both the upper region 310T and the lower region 310B.

Referring to FIG. 6, in some implementations, the guiding section 310S may include an inlet portion 311 and an exit portion 312 opposite the inlet portion 311. For example, the guiding section 310S may include the inlet portion 311 through which the optical signal LT and the reaction gas RG are inflowed, and the exit portion 312 through which the optical signal LT and the reaction gas RG are discharged to the optical detection chamber 210.

The inlet portion 311 is positioned adjacent to the plasma chamber 110 and refers to a region through which the optical signal LT and the reaction gas RG generated from the plasma chamber 110 inflow. The exit portion 312 is arranged adjacent to the optical detection chamber 210 and refers to a region that discharges the optical signal LT and reaction gas RG that flowed in through the inlet portion 311 into the optical detection chamber 210.

In some implementations, the radius of the inscribed circle (or other shape) of the guiding section 310 may decrease from the inlet portion 311 toward the exit portion 312. For example, the guiding section 310 is designed such that the radius of the inscribed circle on the cross-section becomes smaller from the inlet portion 311 to the exit portion 312, thereby satisfying the blocking effect of the reaction gas of the optical signal LT.

Passage of the optical signal LT through the guiding section 310 may improve the linearity of the optical signal LT by forming the radius of the inscribed circle of the guiding section 310 to become narrower as it goes from the inlet portion 311 to the exit portion 312, as described above. The reaction gas RG collides with the inclined portion 310S as it passes through the guiding section 310, to assist in preventing some of the reaction gas RG from being discharged through the exit portion 312, and the discharged reaction gas RG is captured by the inclined portion 310S, thereby being more easily removed in the gas exhaust section 220.

FIG. 6 illustrates an example where the inclined portion 310S is arranged symmetrically in the upper region 310T and the lower region 310B, but this is an example, and other configurations are within the scope of this disclosure. For example, the inclined portion 310S may have a shape in which the diameter of the inscribed circle (or other shape) becomes narrower as it moves from the inlet portion 311 to the exit portion 312, and/or is narrower at the exit portion 312 than at the inlet portion 311, and the shape may be such that the inclined portion 310S arranged in the upper region 310T and the lower region 310B are arranged asymmetrically.

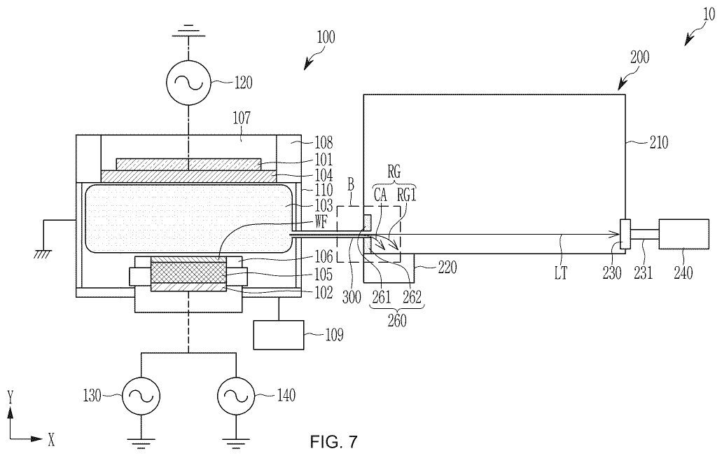

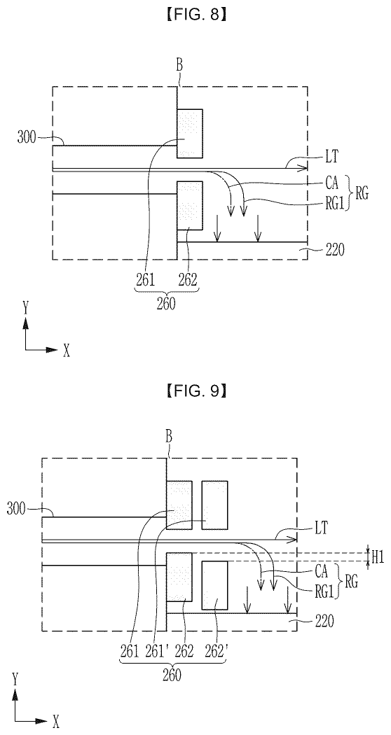

FIG. 7 is a diagram illustrating another example of a plasma monitoring apparatus 10, and FIG. 8 and FIG. 9 are enlarged views of a region B of FIG. 7. The apparatus 10 of FIG. 7 may be substantially similar to that of FIG. 1 except where noted otherwise, and differences therebetween are mainly described.

Referring to FIG. 7 and FIG. 8, in some implementations, the optical detector 200 may include an electrode section 260. For example, the electrode section 260 (or electrode module) may form an electrostatic field to facilitate the movement of the reaction gas RG to the gas exhaust section 220. For example, the reaction gas RG is a mixture of a positive ion CA and the residual reaction gas RG1 such as a negative ion, and includes an excess of the positive ion, and the electrode section 260 may form the electrostatic field to move the positive ion CA or the negative ion in one direction.

In some implementations, the electrode section 260 may include an upper electrode 261 and a lower electrode 262. For example, the electrode section 260 may include the upper electrode 261 and the lower electrode 262 having a different polarity than the upper electrode 261. For example, if the upper electrode 261 has a (+) electrode, the lower electrode 262 may have a (−) electrode.

Since the ratio of the positive ions CA inside the reaction gas RG is often higher than the ratio of the negative ions, the lower electrode may be arranged to have the (−) electrode. By arranging the lower electrode to have the (−) electrode, the positive ion CA occupying the excess in the reaction gas RG may be assisted to move in the downward direction with the Y-axis as a reference, thereby further improving the gas removal efficiency of the gas exhaust section 220.

In some implementations, the interval between the upper electrode 261 and the lower electrode 262 may be adjusted. As the interval between the upper electrode 261 and the lower electrode 262 is adjusted, the strength of the electric field formed may be changed. The interval between the upper electrode 261 and the lower electrode 262 may be controlled to increase the light amount of the optical signal LT and reduce the inflow amount of the reaction gas RG.

FIG. 7 and FIG. 8 only show the increasing in the gas removal efficiency of positive ion CA among the reaction gas RG, but this is an example, and, for example, if it is desired to increase the removal rate of the negative ions due to changes in semiconductor process conditions and designs, or for another reason, the upper electrode 261 may be the (−) electrode and the lower electrode 262 may be the (+) electrode.

Referring to FIG. 9, in some implementations, the electrode section 260 may include a plurality of upper electrodes 261 and 261′ and a plurality of lower electrodes 262 and 262′. For example, the electrode section 260 may include a plurality of upper electrodes and a plurality of lower electrodes to further efficiently separate the positive ion CA and the residual reaction gas RG1 within the reaction gas RG.

In some implementations, the interval between the plurality of upper electrodes 261 and 261′ and the plurality of lower electrodes 262 and 262′ may be adjusted. For example, the interval between the first upper electrode 261 among the plurality of upper electrodes 261 and 261′ and the first lower electrode 262 among the plurality of lower electrodes 262 and 262′ and the interval between the second upper electrode 261′ and the second lower electrode 262′ may be adjusted differently. The intervals between the plurality of upper electrodes 261 and 261′ and the plurality of lower electrodes 262 and 262′ may increase the amount of transmitted light and reduce the inflow amount of the reaction gas.

In some implementations, the plurality of lower electrodes 262 and 262′ may have different heights. For example, the plurality of lower electrodes 262 and 262′ may be arranged with their upper surfaces on different horizontal axes. For example, the plurality of lower electrodes 262 and 262′ may have a height difference H1 between their upper surfaces. For example, the second lower electrode 262 may be placed lower than the first lower electrode 262 to control the positive ion CA to be captured further downward. In FIG. 9, only the height difference of the lower electrodes 262 and 262′ is shown as being different, but this is an example, and the upper electrodes 261 and 261′ may also be at different heights, have lower surfaces at different heights, etc.

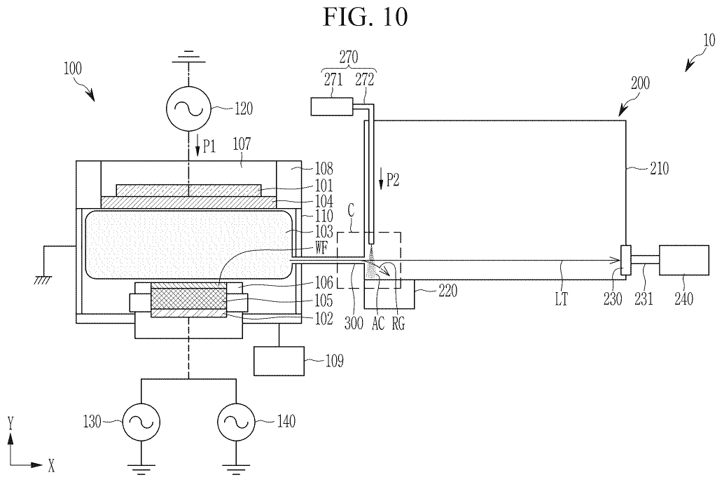

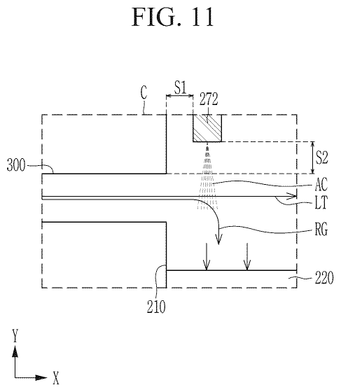

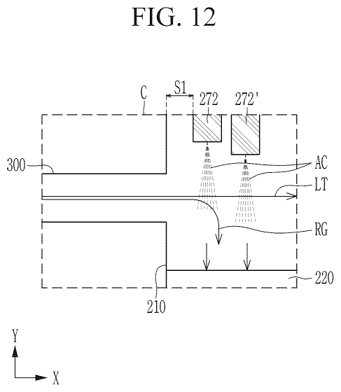

FIG. 10 is a diagram illustrating an example of a plasma monitoring apparatus 10, and FIG. 11 and FIG. 12 are enlarged drawings of a region C of FIG. 10. The apparatus 10 of FIG. 10 may be substantially similar to that of FIG. 1 except where noted otherwise, and differences therebetween are mainly described.

Referring to FIG. 10 and FIG. 11, in some implementations, the optical detector 200 of the plasma monitoring apparatus 10 may include a gas supply section 270 for supplying a cleaning gas AC from top to bottom within the optical detection chamber 210. The gas supply section 270 (or gas supply module) may be arranged within the optical detection chamber 210 and assist in removing the reaction gas RG flowing in from the plasma chamber 110 to the gas exhaust section 220. For example, the gas supply section 270 functions as an air curtain so that the reaction gas RG, which flows in from the plasma chamber 110 together with the optical signal LT, is removed to the gas exhaust section 220by the cleaning gas AC, thereby improving the purity of the optical signal LT, which is transmitted to the first determining section 240.

In some implementations, the gas supply section 270 may include a gas supply chamber 271 and a gas injection orifice 272. The gas supply section 270 may supply the cleaning gas AC included in the gas supply chamber 271 in the direction of the gas exhaust section 220 through the gas injection orifice 272. The cleaning gas AC supplied in the gas supply section 270 may be, as examples, air (Air), argon (Ar), helium (He), neon (Ne), krypton (Kr), xenon (Xe), nitrogen (N₂), hydrogen (H₂), oxidation carbon (CO₂), oxygen (O₂) or a mixed gas thereof.

The gas supply chamber 271 includes the aforementioned cleaning gas AC and may include a high durability material. The high durability material may be, as an example, a stainless steel, a metal such as aluminum, or a material such as ceramic.

In some implementations, the gas supply chamber 271 may include a gas distribution section. For example, the gas distribution section may be positioned inside the gas supply chamber 271 and be designed to uniformly diffuse the cleaning gas AC. For example, the gas distribution section may diffuse the gas by using members such as a porous plate or a multi-layered diffuser to facilitate the injection of the gas through the gas injection orifice 272 in the gas supply chamber 271.

The gas injection orifice 272 may be a member that provides the gas supplied from the gas supply chamber 271 to the gas exhaust section 220. For example, the gas injection orifice 272 may be a pipe through which the gas moves and may be arranged to inject the cleaning gas AC into the gas exhaust section 220 direction so that the reaction gas RG flowing in through the connection section 300 is directed to the gas exhaust section 220 without being diffused inside the optical detection chamber 210.

In some implementations, the gas injection orifice 272 has a pipe shape, and the cross-section shape may include, as examples, any one of a triangle, a quadrangle, or a polygon. The gas injection orifice 272 may have the cross-sections of various shapes as long as it is a structure that may smoothly supply the gas to the gas exhaust section 220.

In some implementations, the gas injection orifice 272 may be positioned above the gas exhaust section 220 and adjacent to the connection section 300. For example, the gas injection orifice 272 may be positioned above the gas exhaust section 220 to prevent the reaction gas RG inflowed through the connection section 300 from diffusing inside the optical detection chamber 210.

In some implementations, the gas injection orifice 272 may be positioned adjacent to the connection section 300 and spaced apart from the exterior wall or interior wall of the optical detection chamber 210 by a first interval S1. For example, the gas injection orifice 272 may be spaced and arranged at the first interval S1 from the optical detection chamber 210, thereby expanding the area through which the cleaning gas AC is diffused when being supplied to the gas exhaust section 220, thereby improving the cleaning power of the reaction gas RG. The first interval S1 may be, for example, 1 mm to 900 mm.

In some implementations, the bottom surface of the gas injection orifice 272 may be positioned higher than the upper surface of the connection section 300. For example, the interval between the bottom surface of the gas injection orifice 272 and the upper surface of the connection section 300 may be arranged to be spaced apart by a second interval S2. The second interval S2 has a value greater than 0, and the gas injection orifice 272 is positioned higher than the connection section 300, so that the diffusion area of the cleaning gas AC is enlarged, and the reaction gas RG may be cleaned by being in contact with it, thereby improving the cleaning power of the reaction gas RG.

In some implementations, the gas supply section 270 may control the pressure of the gas supplied into the optical detection chamber 210. For example, the gas supply section 270 may control the pressure P2 of the gas, thereby easier controlling the reaction gas. More specifically, the pressure P2 of the gas supplied from the gas supply section 270 may be higher than the pressure P1 of the gas supplied to the plasma chamber 110 (e.g., a gas that forms the plasma).

In some implementations, the pressure P2 of the gas supplied from the gas supply section 270 may be at least five times the pressure P1 of the gas supplied to the plasma chamber 110. For example, the pressure P2 of the gas supplied from the gas supply section 270 may be 5 to 15 times the pressure P1 of the gas supplied to the plasma chamber 110. By controlling the pressure of the gas within the aforementioned range, the reaction gas RG may be easily moved toward the high pressure side, and then controlled to be more easily removed by the gas exhaust section 220, thereby providing the optical signal LT with minimized noise.

Referring to FIG. 12, in some implementations, the gas supply section 270 may include a plurality of gas injection orifices 272 and 272′. For example, the gas supply section 270 may include a first gas injection orifice 272 positioned adjacent to the connection section 300, and may include at least one second gas injection orifice 272′ positioned adjacent to the first gas injection orifice 272. By arranging multiple gas injection orifices 272 and 272′, the remaining reaction gas RG that was not cleaned by the first gas injection orifice 272 may be additionally cleaned, thereby further improving the cleaning ability of the reaction gas RG. FIG. 12 illustrates an arrangement of two gas injection orifices (272, 272′), but, depending on the area of the gas exhaust section 220, a greater number of gas injection orifices may be included.

In some implementations, the first gas injection orifice 272 and the second gas injection orifice 272′ may be arranged to have different heights. For example, the first gas injection orifice 272 may be arranged higher than the second gas injection orifice 272′. Since the first gas injection orifice 272 is positioned higher than the second gas injection orifice 272′, the remaining reaction gas RG that is not filtered by the cleaning gas AC injected from the first gas injection orifice 272 may be cleaned more easily.

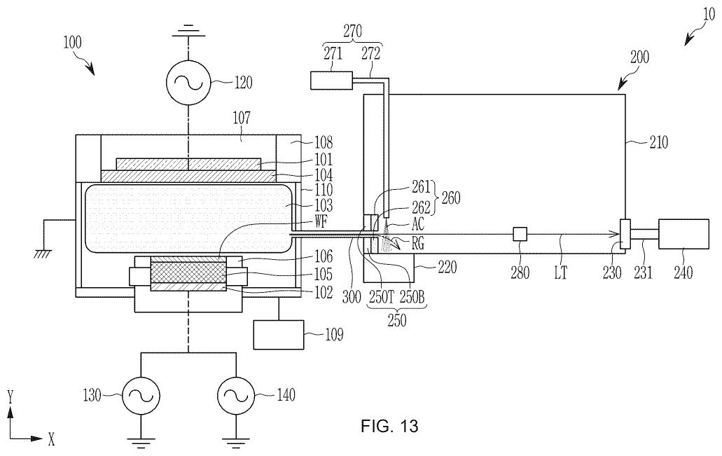

FIG. 13 is a view illustrating an example of a plasma monitoring apparatus 10.

Referring to FIG. 13, the plasma monitoring apparatus 10 may include a substrate processing device 100, an optical detector 200, and a connection section 300 connecting the substrate processing device 100 and the optical detector 200, and the optical detector 200 may include an optical detection chamber 210, a gas exhaust section 220, a first determining section 240, a slit section 250, and an electrode section 260. The description for these components is the same as or similar to the description for the corresponding components above, except where noted otherwise or suggested otherwise by context.

In some implementations, the optical detector 200 of the plasma monitoring apparatus 10 may include a diffraction lattice 280 that separates a signal of the optical signal LT according to a wavelength. For example, the diffraction lattice 280 refers to an optical element for separating or manipulating an optical signal LT into a specific wavelength. For example, the diffraction lattice 280 has periodically arranged grooves or linear structures, and may separate the wavelength components of light by utilizing diffraction and interference phenomena.

In some implementations, the diffraction lattice 280 may control or modify the first optical signal LT1 that the optical signal LT flowing into the optical detector 200 along the connection section 300 is transmitted or diffracted to be directed to the first determining section 240. For example, if the diffraction lattice 280 is a transmissive type, the optical signal LT may pass through the diffraction lattice 280 and be dispersed, and inflow into the first determining section 240. When the diffraction lattice 280 is a reflective or convex type, the optical signal LT may be reflected or diffracted on the surface of the diffraction lattice 280 and inflow into the first determining section 240. FIG. 13 illustrates that the diffraction lattice 280 is the transmissive type, and that the optical signal LT inflowing from the plasma chamber 110 may be transmitted through the diffraction lattice 280 to the first optical signal LT1. As such, wavelength components that are not targets for analysis may be filtered out.

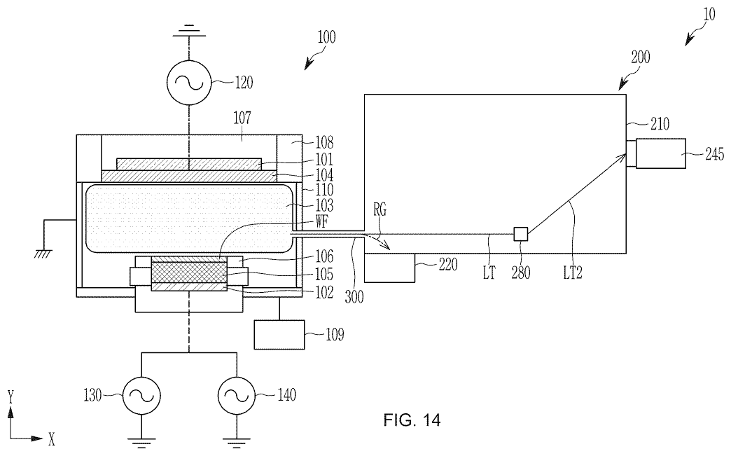

FIG. 14 to FIG. 20 are views illustrating examples of plasma monitoring apparatuses 10.

Referring to FIG. 14, in some implementations, the optical detector 200 includes a diffraction lattice 280 arranged on the same horizontal line as the optical signal LT transmitted through the connection section 300. The diffraction lattice separates the optical signal LT according to wavelength, and a second determining section 245 is configured to analyze plasma processing by using a second optical signal LT2 separated from/by the diffraction lattice 280. For example, the diffraction lattice 280 may separate extreme ultraviolet rays (EUV), which have a shorter wavelength than ultraviolet rays (UV), from the optical signal LT. The EUV rays may be deflected and received by the second determining section 245.

The second determining section 245 may be a device capable of separately analyzing the ultraviolet rays. For example, the second determining section 245 may determine the semiconductor process by analyzing the extreme ultraviolet rays, which the second optical signal LT2. For example, the second determining section 245 may receive the extreme ultraviolet rays separated from the diffraction lattice 280 and analyze the extreme ultraviolet rays to determine characteristics of the plasma process, e.g., the appropriateness of the semiconductor process for the substrate according to the plasma process.

For example, the second determining section 245 may be or include a high-sensitivity detector such as a charge-coupled device (CCD) detector, a complementary metal-oxide-semiconductor (CMOS) detector, a back-illuminated CCD detector, a microchannel plate detector (MCP), a P-N junction CCD (pnCCD) detector, a transition edge sensor (TES), photodiodes, or a hybrid pixel detector. For example, the second determining section 245 may be a CCD detector. The second determining section 245 may be or include a high-sensitivity detector and may provide a high sensitivity and accuracy by considering, or based on, the wavelength characteristics of the extreme ultraviolet rays.

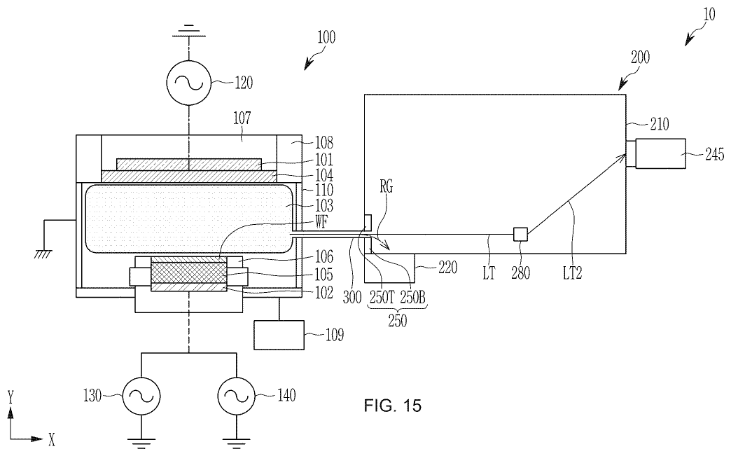

Referring to FIG. 15, in some implementations, the plasma monitoring apparatus 10 may include a slit section 250 and the diffraction lattice 280. The slit section 250 may reduce the reaction gas RG passing through the connection section 300 and increase the light amount of the optical signal LT. Since the plasma monitoring apparatus 10 includes the slit section 250, an amount of residue of the reaction gas RG accumulated on the diffraction lattice 280 may be reduced, and, when the second optical signal LT is transmitted to the second determining section 245, noise associated with the residue may be reduced. The detailed description of the slit section 250 may be as described with respect to FIG. 2 to FIG. 6.

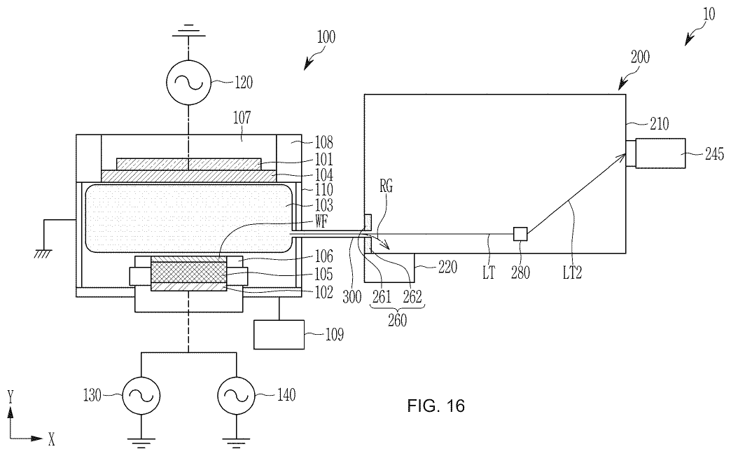

Referring to FIG. 16, in some implementations, the plasma monitoring apparatus 10 includes an electrode section 260 and the diffraction lattice 280. The electrode section 260 may efficiently remove the positive ions CA included in a large amount of the reaction gas RG passing through connection section 300. Since the plasma monitoring apparatus 10 includes the electrode section 260, it is possible to remove the positive ions CA, which are included in a particularly large amount among the reaction gas RG, and which act as noise in the optical detection chamber 210, thereby making detection of extreme ultraviolet rays easier. The detailed description of the electrode section 260 is found in the description of FIG. 7 to FIG. 9.

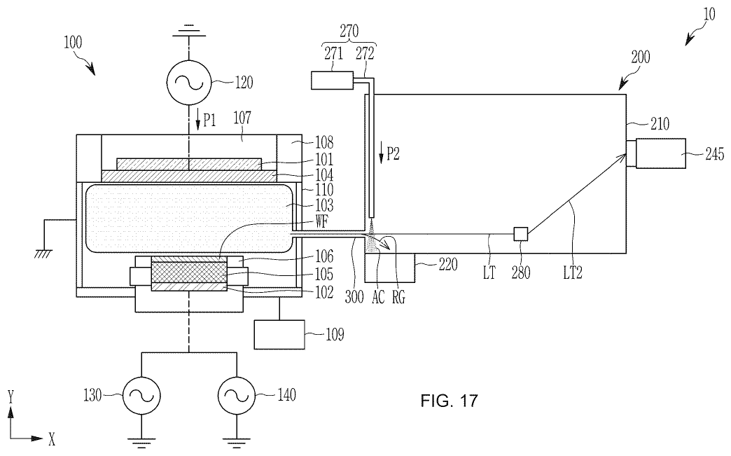

Referring to FIG. 17, in some implementations, the plasma monitoring apparatus 10 may include a gas supply section 270 and the diffraction lattice 280. The gas supply section 270 may assist in removing the reaction gas RG passing through the connection section 300 to the gas exhaust section 220. Since the plasma monitoring apparatus 10 includes the gas supply section 270, it may function as an air curtain to prevent the reaction gas RG from inflowing into the optical detection chamber 210. The detailed description of the gas supply section 270 is found in the contents of FIG. 10 to FIG. 12.

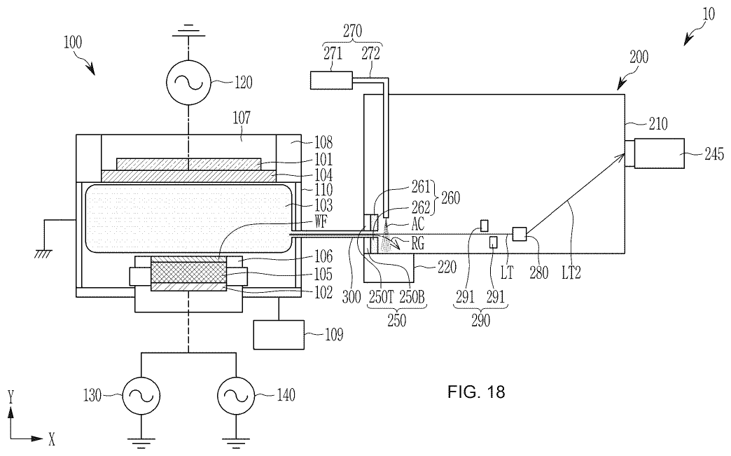

Referring to FIG. 18, in some implementations, an optical detector 200 in the plasma monitoring apparatus 10 may include an optical detection chamber 210, a gas exhaust section 220, a second determining section 245, a slit section 250, an electrode section 260, a gas supply section 270, and a diffraction lattice 280. That is, the various components of the optical detector 200 described with respect to FIGS. 1 to 17 may be included in the optical detector 200, singly or in any combination thereof.

In some implementations, the optical detector 200 may include a corrector 290. The corrector 290 may be adjusted to handle optical signals of short wavelength such as extreme ultraviolet rays. For example, since detection of short wavelengths such as extreme ultraviolet rays may require high accuracy, the corrector 290 may be placed adjacent to the optical signal LT flowing through the connection section 300 to perform a periodic calibration of the optical signal LT.

In some implementations, the corrector 290 may include at least one metal film 291, such as a metal foil. The optical signal LT may pass through the metal film 291 and be absorbed at a specific wavelength. For example, the metal film 291 such as aluminum or silicon absorbs a specific wavelength in the spectrum of extreme ultraviolet rays, and the absorbed wavelength may be used as a reference signal to check and correct the wavelength accuracy of a spectroscopic system.

In some implementations, the metal film 291 may be positioned before the diffraction lattice 280 and above and/or below the optical signal LT. The metal film 291 may be moved into the path of the optical signal LT to perform correction. The metal film 291 may be positioned above and/or below the optical signal LT and move in the vertical direction to perform correction, thereby further improving the accuracy of the second optical signal LT2 determined in the second determining section 245.

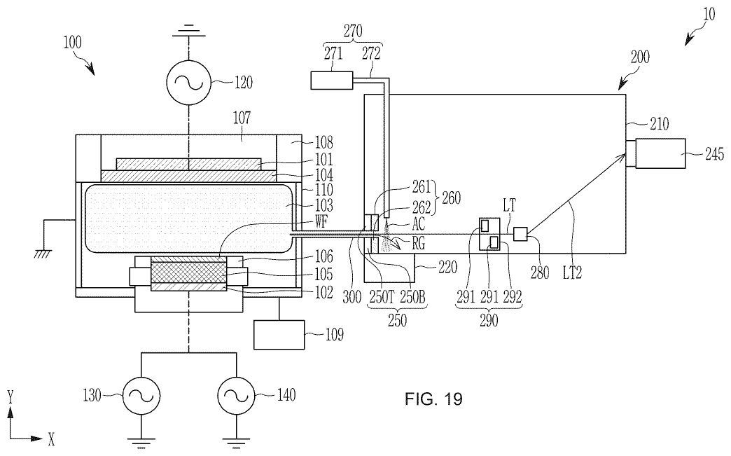

Referring to FIG. 19, in some implementations, the corrector 290 may include at least one metal film 291 and a driver 292. For example, the driver 292 may be controlled with a motor to insert or remove the metal film 291 into the optical path. For example, the corrector 290 of FIG. 19 may improve an automation and convenience by including the driver 292, thereby eliminating the need to manually move the metal film 291.

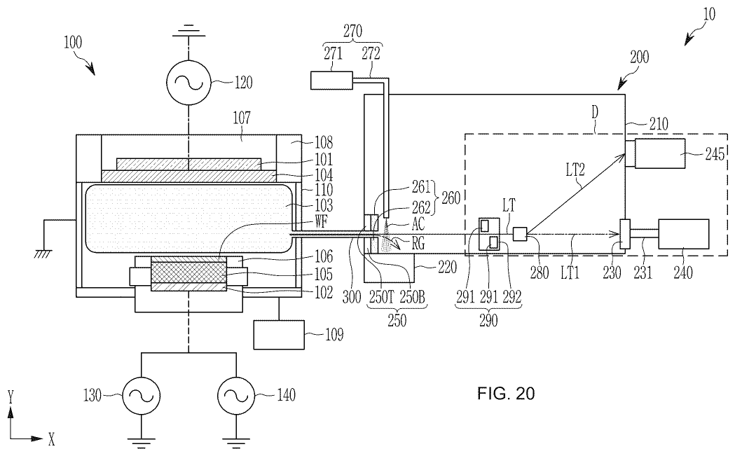

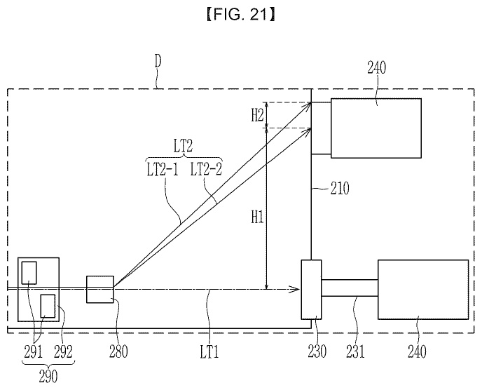

Referring to FIG. 20, in some implementations, the plasma monitoring apparatus 10 may include a substrate processing device 100 and an optical detector 200, and the optical detector 200 may include an optical detection chamber 210, a gas exhaust section 220, a window 230, a first determining section 240, a second determining section 245, and a diffraction lattice 280. The plasma monitoring apparatus 10 simultaneously includes the first determining section 240 and the second determining section 245 to analyze optical signals for wavelengths in multiple wavelength region, thereby enabling more accurate judgment of the semiconductor process. Components of the apparatus 10 of FIG. 20 may have characteristics as described with respect to corresponding components of FIGS. 1 to 19.

For example, the high-reliability optical signal LT from which the noise such as the reaction gas RG has been removed may be spectrally separated into the first optical signal LT1 having a wavelength in the visible light region and the second optical signal LT2 having a wavelength in the extreme ultraviolet rays region through the diffraction lattice 280. The separated first optical signal LT1 may be transmitted to the first determining section 240 through the window 230, and the second optical signal LT2 may be transmitted to the second determining section 245 to determine the substrate processing. As described above, the first determining section 240 and the second determining section 245 may more accurately detect the optical signals LT1, LT2 to determine characteristics of the plasma process, e.g., determine the appropriateness for the semiconductor process by determining the substrate processing, by using the first optical signal LT1 and the second optical signal LT2.

In some implementations, the plasma monitoring apparatus 10 may further include at least one of a slit section 250, an electrode section 260, or a gas supply section 270. The detailed description of the slit section 250, the electrode section 260, and the gas supply section 270 is the same as or similar to that provided above.

FIG. 21 is an enlarged drawing of a region D of FIG. 20.

Referring to FIG. 21, a spectrum calibration process is described to show a method for converting an output value of the second determining section into an accurate wavelength value. Among the metal films 291 within the corrector 290, the metal film 291 positioned at the bottom may absorb the wavelength of λ1 (LT2-1), and the metal film 291 positioned at the top may absorb the wavelength of λ2 (LT2-2). For example, the metal film 291 may correct the wavelength of an optical signal by inserting a material having an absorption in a wavelength region to be observed into the path of the optical signal and detecting it.

For example, the spectrum correction process includes steps of setting correction points, calculating correction factors, and correcting the output values. The wavelengths of the absorption peak wavelengths λ1 (LT2-1) and 22 (LT2-2) of the metal film 291 in the corrector 290 may correspond to values already known as reference values. In the second determining section 245, the output values y1 H1 and y2 H2 corresponding to two absorption peaks are measured.

A linear relationship is established between two reference points (y1, λ1) and (y2, λ2), and a conversion coefficient is calculated to calculate whether a specific output value y of the spectrum corresponds to a wavelength. Next, the specific signal y value output in the second determining section 245 may be substituted into the following formula to obtain the accurate wavelength value.

$$λ = y \times \frac{λ 2 - λ 1}{y 2 - y 1} + λ 1 \qquad Equation 1$$

The second determining section 245 calculates the correction factor by using the absorption peak wavelength values (λ1 (LT2-1)) and (λ2 (LT2-2)) absorbed by the corrector 290 and the output values (y1 (H1) and y2 (H2)) of the second determining section 245 as references, thereby converting all signals into an accurate wavelength unit and then ensuring the accuracy of the signals in the extreme ultraviolet rays spectrum analysis.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination. For example, it will be understood that the components described with respect to any of the apparatuses above can be included in any other of the apparatuses described above.

Although examples have been described in detail above, the scope of the present disclosure is not limited thereto, and various modifications and improvements made by those skilled in the art also fall within the scope of the present disclosure.

What is claimed is:

1. A plasma monitoring apparatus comprising:
an optical detector configured to detect an optical signal generated by plasma in a plasma chamber; and
a connection section configured to connect the plasma chamber and the optical detector,
wherein the optical detector includes:
an optical detection chamber,
a gas exhaust module configured to remove a reaction gas flowing from the plasma chamber into the optical detection chamber through the connection section,
a window arranged to receive the optical signal transmitted from the connection section through the optical detection chamber, and
a sensor configured to detect the optical signal transmitted through the window.

2. The plasma monitoring apparatus of claim 1, comprising:
a slit section in the optical detection chamber adjacent to the connection section, wherein the slit section comprises at least one shutter movable to control an amount of light of the optical signal that is transmitted to the window.

3. The plasma monitoring apparatus of claim 1, wherein:
the gas exhaust module is arranged adjacent to the connection section and at a lower height than the connection section.

4. The plasma monitoring apparatus of claim 1, wherein:
the optical detector includes an electrode module in the optical detection chamber, wherein the electrode module comprises a plurality of electrodes configured to form an electrostatic field, and
wherein the electrode module is arranged such that the electrostatic field moves ions in the reaction gas.

5. The plasma monitoring apparatus of claim 4, wherein:
the plurality of electrodes includes an upper electrode and a lower electrode having a different polarity from the upper electrode.

6. The plasma monitoring apparatus of claim 1, wherein:
the optical detector includes a gas supply module configured to supply a gas into the optical detection chamber such that the gas forms an air curtain.

7. The plasma monitoring apparatus of claim 6, wherein the gas supply module includes a gas injection orifice configured to provide the gas downward in the optical detection chamber, and
wherein the gas injection orifice is positioned above an intake of the gas exhaust module and adjacent to the connection section.

8. The plasma monitoring apparatus of claim 7, wherein the gas supply module includes at least one second gas injection orifice positioned adjacent to the gas injection orifice.

9. The plasma monitoring apparatus of claim 6, wherein the gas supply module is configured to provide the gas into the optical detection chamber with a pressure that is higher than a pressure of a gas supplied to the plasma chamber to form the plasma.

10. The plasma monitoring apparatus of claim 1, wherein:
the connection section includes a guiding section shaped to block a portion of the reaction gas from inflowing into the optical detection chamber.

11. The plasma monitoring apparatus of claim 10, wherein the guiding section comprises an inclined surface in the connection section.

12. The plasma monitoring apparatus of claim 10, wherein the guiding section includes:
an inlet portion adjacent to the plasma chamber and into which the optical signal and reaction gas flow, and
an exit portion adjacent to the optical detection chamber and through which the optical signal and the reaction gas are discharged into the optical detection chamber, and
wherein a radius of an inscribed shape of the guiding section becomes smaller from the inlet portion toward the exit portion.

13. The plasma monitoring apparatus of claim 1, wherein the sensor comprises at least one of: an optical emission spectroscopy (OES) module, a laser absorption spectroscopy (LAS) module, a tunable diode laser absorption spectroscopy (TDLAS) module, a laser-induced breakdown spectroscopy module, a Fourier-transform infrared spectroscopy module, a cavity ring-down spectroscopy (CRDS) module, an X-ray photoelectron spectroscopy (XPS) module, a tunable laser spectroscopy module, or an ellipsometry module.

14. The plasma monitoring apparatus of claim 1, wherein the optical detector includes a diffraction lattice configured to separate the optical signal based on wavelength.

15. A plasma monitoring apparatus comprising:
an optical detector configured to detect an optical signal generated by plasma in a plasma chamber; and
a connection section configured to connect the plasma chamber and the optical detector,
wherein the optical detector includes:
an optical detection chamber,
a gas exhaust module configured to remove a reaction gas flowing from the plasma chamber into the optical detection chamber through the connection section,
a diffraction lattice arranged to receive the optical signal transmitted from the connection section through the optical detection chamber, wherein the diffraction lattice is configured to separate the optical signal based on wavelength, and
a sensor configured to detect a first portion of the optical signal that is separated by the diffraction lattice.

16. The plasma monitoring apparatus of claim 15, wherein the optical detector includes a metal film configured to be on an optical path of the optical signal in the optical detection chamber.

17. The plasma monitoring apparatus of claim 16, wherein the optical detector comprises a driver configured to move the metal film in and out of the optical path.

18. The plasma monitoring apparatus of claim 15, wherein the diffraction lattice is configured to separate the first portion of the optical signal having an extreme ultraviolet (EUV) wavelength from a second portion of the optical signal having a wavelength higher than EUV.

19. The plasma monitoring apparatus of claim 18, wherein the optical detector comprises a second sensor configured to detect the second portion of the optical signal.

20. A plasma monitoring apparatus comprising:
an optical detector configured to detect an optical signal generated by plasma in a plasma chamber; and
a connection section configured to connect the plasma chamber and the optical detector,
wherein the optical detector includes:
an optical detection chamber,
a gas exhaust module configured to remove a reaction gas flowing from the plasma chamber into the optical detection chamber through the connection section,
a diffraction lattice arranged to receive the optical signal transmitted from the connection section through the optical detection chamber, wherein the diffraction lattice is configured to separate the optical signal into a first optical signal and a second optical signal, wherein the second optical signal has a shorter wavelength than the first optical signal,
a window arranged to receive the first optical signal,
a first sensor configured to detect the first optical signal transmitted through the window, and
a second sensor configured to detect the second optical signal.
